(19) United States
(12) Patent Application Publication
(10) Pub. No.: US 2012/0133215 A1
(43) Pub. Date: May 31, 2012

(54) POSITIONING METHOD OF MOVABLE APPARATUS AND POSITIONING SYSTEM

(76) Inventors: Ming-Iu Lai, Taipei (TW); Shih-Chi Lin, Taipei (TW)

(21) Appl. No.: 13/306,784

(22) Filed: Nov. 29, 2011

Related U.S. Application Data
(60) Provisional application No. 61/418,156, filed on Nov. 30, 2010.

(51) Int. Cl. H01F 38/14; G01R 27/28

(52) U.S. Cl. 307/104; 324/654

(57) ABSTRACT

A positioning method is applied to a movable apparatus and a positioning station. The movable apparatus includes an inducting coil, and the positioning station includes a transmitting coil. The positioning method includes the following steps: transmitting a testing signal via the transmitting coil, inducting the testing signal from the transmitting coil via the inducting coil, measuring an induction value of the inducting coil and driving the movable apparatus to move towards the positioning station according to the induction value.

### CROSS REFERENCE TO RELATED APPLICATIONS

The Non-provisional application claims priority to U.S. provisional patent application with Ser. No. 61/418,156 filed on Nov. 30, 2010. This and all other extrinsic materials discussed herein are incorporated by reference in their entirety.

### BACKGROUND OF THE INVENTION

1. Field of Invention

The invention relates to a positioning method and, more particularly, to a positioning method of a movable apparatus and a positioning system.

2. Related Art

A movable electronic device may automatically enter a station for charging. Conventionally, the movable electronic device has an infrared radiation (IR) sensor and is charged by a contacting charging method. FIG. 1 is a schematic diagram showing that a conventional movable electronic device enters a station automatically for charging. The movable electronic device 101 includes an IR sensor 102, and the charging station 111 includes an IR sensor 112 and two metal electrodes 113 for contacting the movable electronic device 101 to charge. If the movable electronic device needs to be charged, it has to go back to the charging station automatically to contact the metal electrodes 113 on the charging station. In the positioning process that goes back to the charging station, the movable electronic device 101 should first positioned in front of the IR sensor 112 of the charging station 111, and then moves straightly towards the charging station 111 along a path 121. However, due to the detectable area 122 that emitted by IR in the current position method is limited; the positioning process is easy to be missed. If a missing occurs, the movable electronic device 101 should move away from the charging station 111 and execute the positioning process again.

FIG. 2 is a schematic diagram showing a second conventional movable electronic device enters a station automatically for charging. An IR sensor 114 is further included in the charging station 111. At the beginning of the positioning process, the movable electronic device moves into a detectable area 124 with left and right boundaries that emitted by two IR sensors 112, 114, and then the movable electronic device faces inwards and enters the station along a derious path 123. Since more than one IR sensor is used, the detectable area is larger than that showed in FIG. 1, and the missing rate is decreased. However, in the second positioning process, the derious moving path of the movable electronic device 101 is long, and thus the positioning time increases.

Additionally, the elements that equipped on the movable electronic devices are not fully used in conventional positioning methods. For example, in the current automatic positioning process for charging, video lens and image analysis technology that equipped on the movable electronic device are not used. Furthermore, since the conventional charging method is achieved by physical contact, the charging station should be leaned on a wall or a pillar to withstand impact while the movable electronic device is physically contact the charging station to be charged and ensures that the electrodes contact the movable electronic device firmly, which limits the location chosen and the positioning process of the charging station.

### SUMMARY OF THE INVENTION

A positioning method applied to a movable apparatus and a positioning station is provided. The movable apparatus includes an inducting coil, and the positioning station includes a transmitting coil. The positioning method includes following steps: transmitting a testing signal via the transmitting coil, inducting the testing signal from the transmitting coil via the inducting coil, measuring an induction value of the inducting coil and driving the movable apparatus towards the positioning station according to the induction value.

A positioning system includes a movable apparatus and a positioning station is also disclosed herein. The movable apparatus includes a processing unit and an inducting coil electrically connected to the processing unit. The positioning station includes a power transmitting unit and a transmitting coil, and the power transmitting unit is electrically connected to the transmitting coil and drives the transmitting coil to transmit a testing signal. The inducting coil inducts the testing signal from the transmitting coil, and the processing unit measures an induction value of the inducting coil and drives the movable apparatus to move towards the positioning station according to the induction value.

As stated above, the positioning method of the movable apparatus is achieved by using a specific relation between an interval and an induction value, the interval is between the inducting coil and the transmitting coil, and the induction value is inducted from the transmitting coil by the inducting coil. The transmitting coil is used to transmit the testing signal, and the inducting coil is used to induct the testing signal and get the induction value. Thus, the movable apparatus is driven according to the induction value, and the inducting coil of the movable apparatus and the transmitting coil of the positioning station are overlapped to finish the positioning. After the positioning, the inducting coil of the movable apparatus and the transmitting coil of the positioning station are used to charge the movable apparatus or exchange data.

The movable apparatus is charged by the electromagnetic induction, instead of the conventional contact method, which enlarges the detectable area, decreases the positioning missing rate and improves positioning efficiency.

These and other features, aspects and advantages of the present invention will become better understood with regard to the following description, appended claims, and accompanying drawings.

### BRIEF DESCRIPTION OF THE DRAWINGS

FIG. 1 and FIG. 2 are schematic diagrams showing that conventional movable electronic devices enter a station automatically for charging;

FIG. 3 is a flow chart showing steps of a positioning method of a movable apparatus in a first embodiment;

FIG. 4 is a block diagram showing a positioning system in an embodiment;

FIG. 5 is an arithmetic price scale showing relationship of an induction value and an interval between the inducting coil and the transmitting coil of the movable apparatus in an embodiment;

FIG. 6 is a schematic diagram showing a movable apparatus and a positioning station applying a positioning method in an embodiment; and

FIG. 7 is a flow chart showing detailed steps of the positioning method in an embodiment.

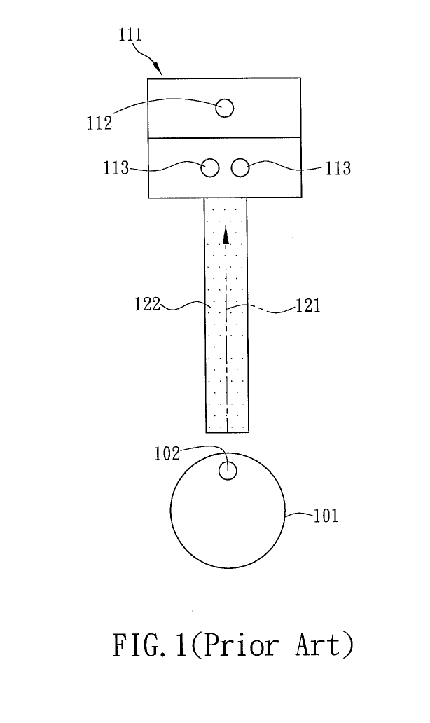

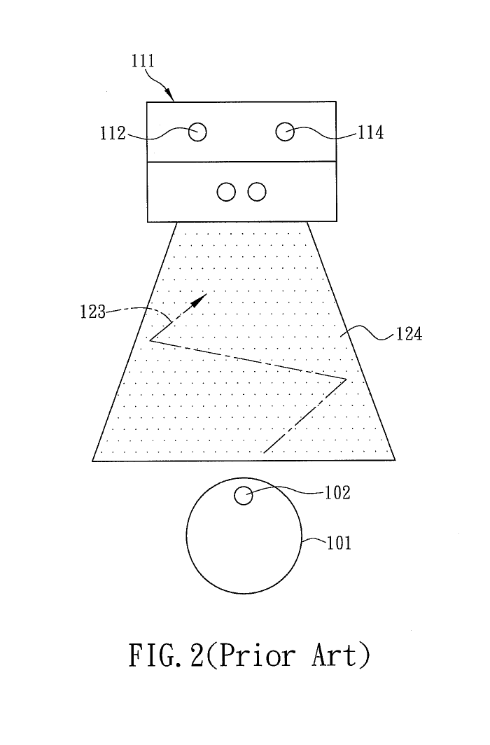

### DETAILED DESCRIPTION OF THE INVENTION

A positioning method of a movable apparatus in an embodiment is illustrated with relating figures, and the same symbols denote the same components.

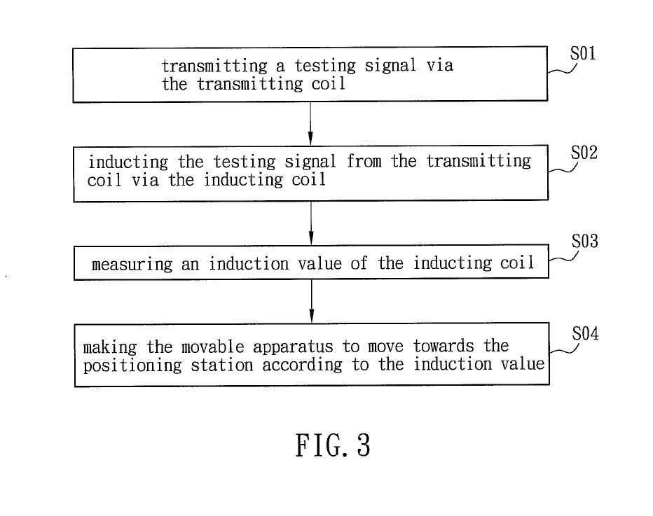

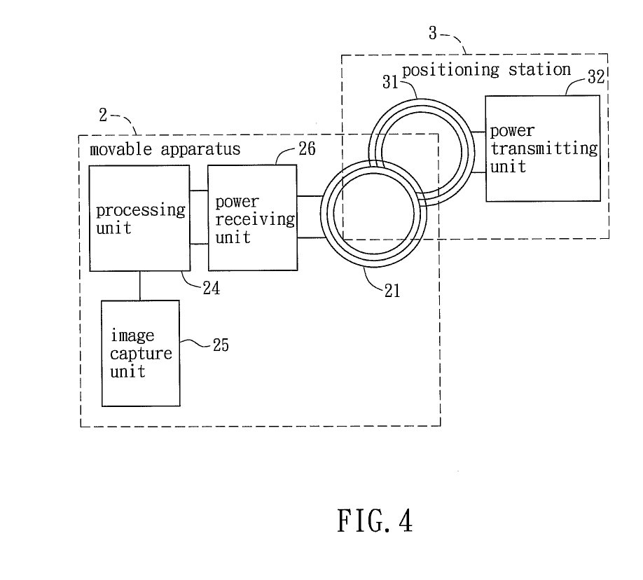

FIG. 3 is a flow chart showing steps of a positioning method of a movable apparatus in an embodiment, and FIG. 4 is a block diagram showing a positioning system in an embodiment. The positioning system includes a movable apparatus 2 and a positioning station 3. The movable apparatus 2 includes a processing unit 24 and an inducting coil 21 electrically connected to the processing unit 24. The positioning station 3 includes a power transmitting unit 32 and a transmitting coil 31 connected to the power transmitting unit 32. The positioning method is applied to the movable apparatus 2 and the positioning station 3. The positioning method includes following steps: transmitting a testing signal via the transmitting coil 31 (Step S01), inducting the testing signal from the transmitting coil 31 via the inducting coil 21 (Step S02), measuring an induction value (such as a voltage value) of the inducting coil 21 (Step S03) and driving the movable apparatus 2 to move towards the positioning station 3 according to the induction value (Step S04).

When the transmitting coil 31 of the positioning station 3 transmits the testing signal, the inducting coil 21 of the movable apparatus 2 generates an inducting voltage, and the induction value changes with the various distance between the two coils. Consequently, the changes of the induction value bring to know the distance between the two coils (the inducting coil and the transmitting coil), and drives the movable apparatus to move towards the positioning station 3 accordingly to complete the positioning process. More detail, the processing unit 24 measures an induction value of the inducting coil 21 and drives the movable apparatus 2 to move towards the positioning station 3 according to the induction value.

After the positioning process is completed, the positioning station 3 can charge the movable apparatus 2 or exchange data via the electromagnetic induction between the inducting coil 21 and the transmitting coil 31.

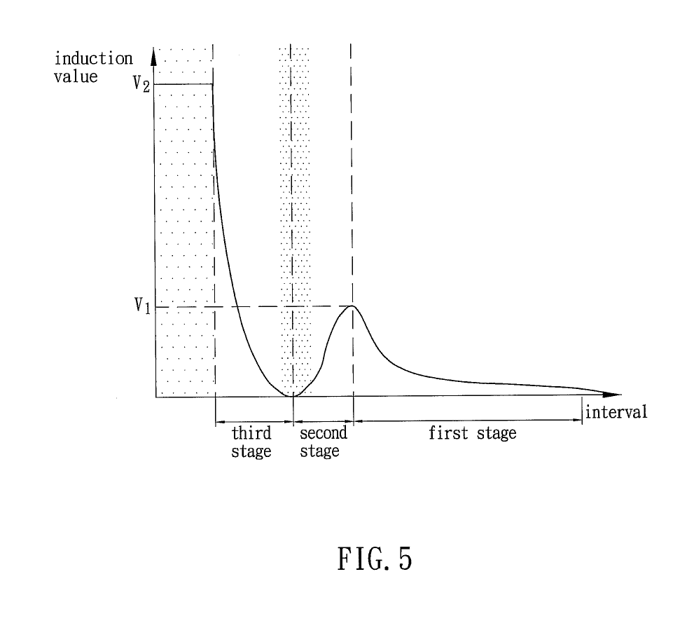

FIG. 5 is a curve showing relationship of an induction value and an interval between the inducting coil 21 and the transmitting coil 31 of the movable apparatus 2 in an embodiment. X-axis represents the distance between the center of the inducting coil 21 of the movable apparatus 2 and the center of the transmitting coil 31 of the positioning station 3, and Y-axis represents the induction value.

In a first stage in FIG. 5, the induction value increases and is not larger than a preset value. The induction value increases gradually, and it means that the inducting coil is approaching the transmitting coil. In an embodiment, the preset value may be an induction value V1, and the induction value V1 is measured in advance and inputted to the movable apparatus 2. In the moving process of the movable apparatus 2, the distance between the two coils can be speculated according to the induction value.

In a second stage in FIG. 5, the induction value decreases. After the induction value reaches the induction value V1, as the distance between the center points of two coils decreases, the induction value decreases. In the second stage, the processing unit 24 drives the movable apparatus 2 to slow down, so as to avoid that the movable apparatus 2 moves too fast to get a wrong determination. When the induction value decreases to zero, the system determines that the distance between two centers of two coils is X. According to the electromagnetic theory, the value of X is slightly smaller than a sum of radiuses of two coils. The precise value of X can be measured in practice.

In a third stage, the induction value increases rapidly and reaches a constant value, such as an induction value V2. When the induction value reaches the constant value V2, it means that the two coils are overlapped. In the positioning method, after the induction value reaches the constant value V2, the processing unit 24 stops the movable apparatus 2. Thus, the positioning of the movable apparatus is finished.

The positioning method in an embodiment further includes a step of charging the movable apparatus or exchanging data via the transmitting coil and the inducting coil after the movable apparatus is positioned.

Moreover, in the positioning method in an embodiment, the image capturing and the image recognizing functions can also be used to assist the positioning of the movable apparatus. Thus, the positioning method further includes the step that capturing at least one image of the positioning station, recognizing the image according to the image and driving the movable apparatus according to a result of the image recognizing. In the embodiment, the movable apparatus 2 may further include an image capture unit 25 electrically connected to the processing unit 24. The processing unit 24 triggers the image capture unit 25 to capture at least one image of the positioning station 3, then to recognize the image accordingly and drives the movable apparatus 2 to move towards the positioning station 3. The positioning method also can be used in a long-distance positioning which the induction value of the inducting coil 21 of the movable apparatus is always zero. In the positioning method in an embodiment, both the result of the image recognizing and the induction value are used to drive the movable apparatus.

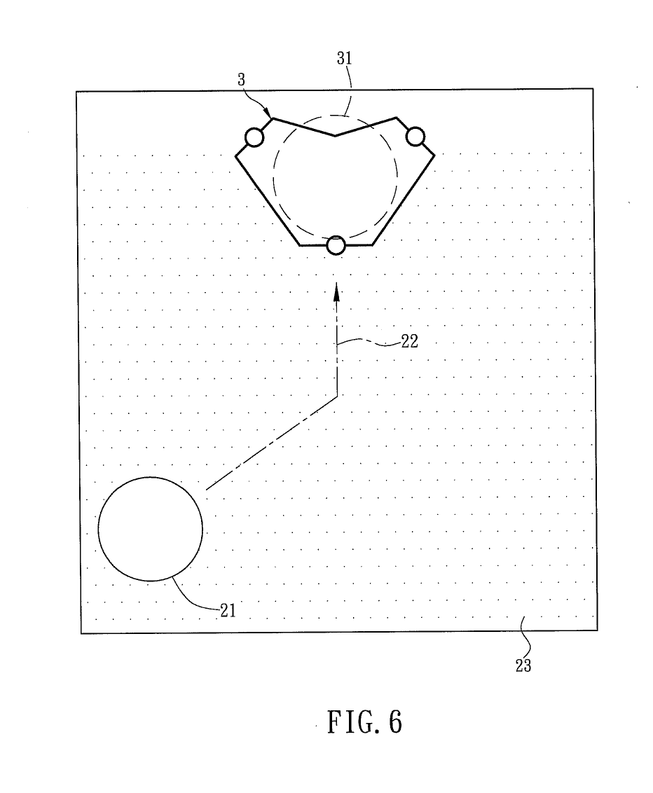

FIG. 6 is a schematic diagram showing a movable apparatus and a positioning station 3 applying a positioning method in an embodiment FIG. 6. Only the inducting coil 21 of the movable apparatus and the transmitting coil 31 of the positioning station 3 are shown in FIG. 6 for convenient illustration. Since electromagnetic induction instead of IR sensing is used in the embodiment, the movable apparatus can approach the positioning station 3 in any path 22 from any direction to achieve positioning. Thus, the detectable area 23 is enlarged, the positioning missing rate is greatly decreased and the positioning efficiency is improved.

Type of the movable apparatus is not limited herein, and it may be a robot, a vehicle (such as a car), an electrical appliance (such as a dust cleaner) or other movable devices.

After the positioning process is completed, the movable apparatus can be charged or data can be exchanged, therefore, “charging” is taken as an example herein. In an embodiment, the movable apparatus 2 further includes a power receiving unit 26 electrically connected to the inducting coil 21 and the processing unit 24. After the movable apparatus 2 stops and completes the positioning process, the power transmitting unit 32 of the positioning station 3 provides power to the transmitting coil 31. Since the transmitting coil 31 and the inducting coil 21 are overlapped, the inducting coil 21 provides power to the power receiving unit 26 via the electromagnetic induction for charging.

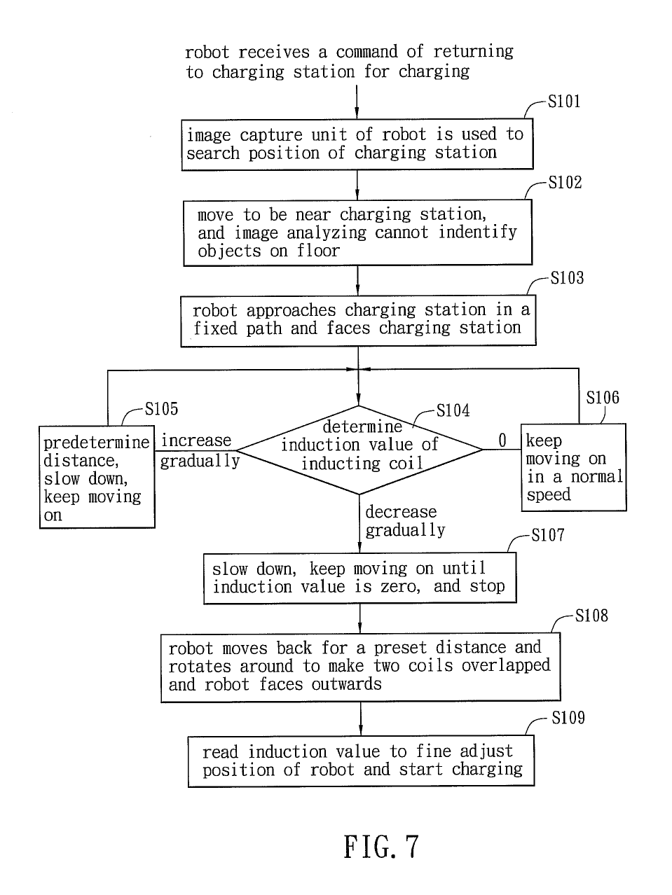

FIG. 7 is a flow chart showing detailed steps of the positioning method in an embodiment. The movable apparatus is a robot and the positioning station is a charging station for example. First, the robot receives a command of returning to the charging station for charging. Then, the image capture unit of the robot is used to search the position of the charging station (S101), and the step includes capturing an image of the charging station and analyzing the image. According to image analyzing result, the robot moves to near the charging station, meanwhile, the distance between the robot and the charging station make the image analyzing cannot identify objects on the floor (S102). The robot approaches the charging station in a fixed path and faces the charging station (S103). Then, the robot determines the induction value (taking a voltage value as an example) of the inducting coil (S104). If the induction value increases, the robot predetermines the distance, then slows down, and keeps moving on (S105), and determines the induction value again. The Step 105 corresponds to the first stage in FIG. 5. If the induction value is zero, the robot keeps moving on in a normal speed (S106) and determines the induction value again. If the induction value gradually decreases, the robot slows down, then keeps moving on until the induction value is zero, and then the robot stops (S107). The Step 107 corresponds to the second stage in FIG. 5. The robot moves back for a preset distance and rotates around to make the two coils overlapped and make the robot face outwards (S108). Finally, the position of the robot is tuned by the induction value (corresponding to the third stage in FIG. 5), and then the charging starts (S109).

Although the present invention has been described in considerable detail with reference to certain preferred embodiments thereof, the disclosure is not for limiting the scope. Persons having ordinary skill in the art may make various modifications and changes without departing from the scope. Therefore, the scope of the appended claims should not be limited to the description of the preferred embodiments described above.

What is claimed is:

1. A positioning method of a movable apparatus, applied to a movable apparatus and a positioning station, wherein the movable apparatus includes an inducting coil and the positioning station includes a transmitting coil, the positioning method comprising:
transmitting a testing signal via the transmitting coil;
inducting the testing signal from the transmitting coil via the inducting coil;
measuring an induction value of the inducting coil; and
driving the movable apparatus according to the induction value.

2. The positioning method according to claim 1, wherein the positioning method further includes:
capturing at least an image of the positioning station;
recognizing the image; and
driving the movable apparatus according to a result of the image recognizing.

3. The positioning method according to claim 1, wherein in the step of driving the movable apparatus according to the induction value, if the induction value increases and is not larger than a preset value, the movable apparatus is driven towards the transmitting coil to make the induction value increase.

4. The positioning method according to claim 1, wherein in the step of driving the movable apparatus according to the induction value, if the induction value decreases, moving speed of the movable apparatus is decreased.

5. The positioning method according to claim 1, wherein in the step of driving the movable apparatus according to the induction value, if the induction value decreases to zero, the movable apparatus is driven to increase the induction value rapidly.

6. The positioning method according to claim 5, wherein when the induction value rapidly increases and reaches a constant value, the movable apparatus stops.

7. The positioning method according to claim 6, wherein when the movable apparatus stops, the movable apparatus is charged via the transmitting coil and the inducting coil.

8. A positioning system, comprising:
a movable apparatus including a processing unit and an inducting coil electrically connected to the processing unit and
a positioning station including a power transmitting unit and a transmitting coil, wherein the power transmitting unit is electrically connected to the transmitting coil and makes the transmitting coil to transmit a testing signal, the inducting coil inducts the testing signal from the transmitting coil, and the processing unit measures an induction value of the inducting coil and drives the movable apparatus to move towards the positioning station according to the induction value.

9. The positioning system according to claim 8, wherein the movable apparatus further includes:
an image capture unit electrically connected to the processing unit, wherein the processing unit drives the image capture unit to capture at least one image of the positioning station, recognize the image and drive the movable apparatus according to result of the image recognizing.

10. The positioning system according to claim 8, wherein if the induction value increases and is not larger than a preset value, the processing unit drives the movable apparatus to approach the transmitting coil to make the induction value increase.

11. The positioning system according to claim 8, wherein if the induction value decreases, the processing unit decreases moving speed of the movable apparatus.

12. The positioning system according to claim 8, wherein if the induction value deceases to zero, the processing unit drives the movable apparatus to make the induction value increase rapidly.

13. The positioning system according to claim 12, wherein after the induction value rapidly increases and reaches a constant value, the processing unit drives the movable apparatus to stop.

14. The positioning system according to claim 13, wherein the positioning system further includes:
a power receiving unit electrically connected to the inducting coil and the processing unit, wherein after the movable apparatus stops, the processing unit makes the power receiving unit to receive power from the transmitting coil and the inducting coil.
